(19) United States
(12) Patent Application Publication
(10) Pub. No.: US 2012/0054125 A1
(43) Pub. Date: Mar. 1, 2012

(54) RESOURCE MANAGEMENT AND CONTROL SYSTEM

(76) Inventors: ERIC DOUGLASS CLIFTON, San Marcos, CA (US); Jonathan Howard Chasson, San Diego, CA (US)

(21) Appl. No.: 13/224,279

(22) Filed: Sep. 1, 2011

Related U.S. Application Data
(60) Provisional application No. 61/379,377, filed on Sep. 1, 2010.

(51) Int. Cl. G01R 11/56; G06F 15/173; G06F 19/00

(52) U.S. Cl. 705/412; 702/122; 709/223

(57) ABSTRACT

A resource management and control system includes real-time visibility to energy and water consumption. The resource management platform is flexible and allows users to create a system to suit their individual needs, and to make changes to that platform as their needs change and new needs arise. The resource management and control system monitors electricity and gas consumption, solar production, and water use in real time. The control system includes a number of wireless access nodes for interfacing with the various systems within a property, and also includes monitoring, diagnostic and alerting capabilities. Billing system integration provides historical data for the cost of resource usage and production relative to time, geography and consumer service level agreements and allows the user the ability to directly correlate consumption behaviors with cost implications. Autonomously operating control processes are incorporated to automatically configure and control devices for optimal resource consumption and application.

### RELATED APPLICATION

This application claims the benefit of priority to United States Provisional Patent Application Ser. No, 61/379,377, entitled “Building Management and Control System” filed Sep. 1, 2010, currently co-pending, and fully incorporated herein by this reference.

### BACKGROUND OF THE INVENTION

The conservation of electricity, gas and water has become a key concern across the globe. With the high cost of energy production, and the often devastating effects such production has on the environment, limiting the use of electricity and gas has never been more important. Moreover, with the ever-increasing population and its need for a reliable water supply, the real fear of drought has caused many municipalities to force conservation on its residents through regulation and legislation.

Clearly, the majority of the population is not only mindful of the need for conservation, but willing to conserve their use of electricity, gas and water for the benefit of the environment and associated cost savings. However, aside from the simplest acts of turning off lights, reducing heating and air conditioning levels, and limiting water consumption, the ordinary consumer is not equipped to determine the actual results of their conservation efforts. As a result, most consumers are not able to identify their largest energy consuming appliances or habits, or what is responsible for the majority of the water consumption in their home or business.

In an effort to decrease the use of electricity, gas and water, various control devices have been developed. For instance, timers, photo-cells, and motion detection devices have been used for controlling lighting for many years. Likewise, the consumption of gas is greatly limited by the use of programmable thermostats which account for weekly occupancy and temperature setting variations. Landscapes have long been the beneficiary of programmable irrigation controllers allowing for set periodic watering schedules.

While these various controls systems have been used to decrease overall consumption, they seldom provide a user with the real-time feedback necessary to appreciate the specific savings of electricity, gas or water, or help take advantage of the lower energy costs associated with off-peak usage. Thus, a user may incorporate some of these conservation devices into their home, may see a slight reduction in overall monthly costs, but have little or no information related to their real-time consumption, the cost of that consumption, and their consumption rate as compared to neighbors, region, or community guidelines.

Studies show that a major contributor in reducing utility consumption and emissions is consumer awareness. An active in-home-display is the best medium in providing consumers with this information. Residents, builders and developers have an immediate need for products that can help them comply with the ever changing building codes for greenhouse gas emissions, energy and water conservation standards and guidelines. The market for conservation products has never been better, which means the demand for the resource management and control system of the present invention has never been stronger.

In light of the above, it would be advantageous to provide a resource management and control system designed specifically for the residential and light commercial customer. This resource management and control system would provide consumers with the information they need to monitor and control utility budgets by automatically and intelligently managing consumption within their homes, and by staying connected anytime, anywhere, and to any device.

It would also be advantageous to provide a resource management and control system having a flexible architecture that allows end users to create a system that suits their individual needs, and which can be modified as the user's needs evolve.

It would be further advantageous to provide a resource management and control system that is easy to use and comparatively cost effective, thereby providing an ordinary resident the tools that he or she needs to maximize their conservation efforts, thereby decreasing the overall consumption of electricity, gas and water in the community.

### SUMMARY OF THE INVENTION

The resource management and control system of the present invention is an affordable residential and light commercial resource management system that grows with the user. It brings real-time visibility to energy and water consumption while helping consumers set conservation goals and maintain budgets. Simply stated, the resource management and control system of the present invention makes conservation simple and maintainable. The flexible platform allows users to create a system to suit their individual needs, and to make changes to that platform as their needs change and new needs arise.

The resource management and control system of the present invention monitors electricity and gas consumption, solar production, and water use in real time, independent of the utility installed smart meter. The control system may also monitor and control the high utility consumption devices in the home or light commercial establishment. Moreover, the system can provide time-of-use control thereby maximizing energy and cost savings when considering the increased energy costs typically charged during peak periods of use.

The control system of the present invention also includes a number of wireless access nodes for interfacing with the various systems within the property. For example, wireless thermostat and wireless irrigation controllers are automatically adjusted based on up-to-date environmental data to minimize energy consumption while saving time and money.

In addition to the basic measurement and control of electricity, gas, and water, the present invention also includes monitoring, diagnostic and alerting capabilities. For instance, home and business owners can be notified when an appliance is not operating efficiently before that appliance completely fails, thereby avoiding costly repair or replacement. This monitoring further enhances the conservation efforts of the user since malfunctioning appliances typically use more energy.

The present invention also includes billing system integration providing historical data for the cost of resource usage and production relative to time, geography and consumer service level agreements. Billing system integration allows the user the ability to directly correlate consumption behaviors with cost implications.

The present invention further includes the use of location services to sense the proximity of the consumer to the building. This allows the user the ability to configure the resource management system to initiate heating or cooling the premises, or to turn on lights and appliances as desired.

The present invention also includes a method to incorporate autonomously operating control processes that automatically configure and control devices for optimal resource consumption and application. For example, this allows the user the ability to use an automated system to control the user's irrigation system.

### DESCRIPTION OF THE DRAWING

The nature, objects, and advantages of the present invention will become more apparent to those skilled in the art after considering the following detailed description in connection with the accompanying drawings, in which like reference numerals designate like parts throughout, and wherein:

FIG. 1 is a system-level diagram of the resource management and control system of the present invention detailing a residential energy and water monitor and control system including a home display server, intra-home communications network server, and interfaces to monitor and control utility inputs, and a central server in communication with the home display server and remote user stations;

FIG. 2 is a block diagram of the resource management and control system of the present invention showing a central server having a server computer and associated database, in communication with a number of remote devices, external information sources, and with the in-home control station comprising a central processing unit, memory, database, user interface, and communication interfaces for a variety of nodes (electric, gas, water, irrigation, solar, etc.);

FIG. 3 is a diagrammatic representation of an electrical node module of the resource management and control system of the present invention having network, radio, status, and power LED indicators, and a number of current measurement and voltage measurement inputs to sense the electrical energy being utilized by the home;

FIG. 4 is a diagrammatic representation of a water node module of the resource management and control system of the present invention having network, radio, status, and power LED indicators, and a primary flow rate input with a corresponding control output, and a secondary flow rate input with a corresponding control output;

FIG. 5 is a diagrammatic representation of an irrigation node module of the resource management and control system of the present invention having network, radio, status, and power LED indicators, a irrigation voltage input, and a number of irrigation zone control outputs;

FIG. 6 is a diagrammatic representation of a gas node module of the resource management and control system of the present invention having network, radio, status, and power LED indicators, and a flow rate input and a control output to actuate a flow valve;

FIG. 7 is a diagrammatic representation of an environmental node module of the resource management and control system of the present invention having network, radio, status, and power LED indicators, and a number of external environmental measurement inputs including multiple zone temperatures, a humidity sensor, and multiple radiation level sensors;

FIG. 8 is a diagrammatic representation of a solar node module of the resource management and control system of the present invention having network, radio, status, and power LED indicators, and a voltage and current input for sensing levels of a solar panel array, and an inverter measurement input to sense the output voltage of the inverter associated with the solar panel array;

FIG. 9 is a block diagram of the circuitry of a typical energy module of the resource management and control system of the present invention, including a core processor having a power supply and status driver, and in communication with a Zig Bee wireless module and electric power interface which receives voltage and current levels from three power lines, such as different phases of multi-phase power to a property;

FIG. 10 is a is a block diagram of the circuitry of a typical flow module of the resource management and control system of the present invention, including a core processor having a power supply, temperatures sensor and status driver, and in communication with a ZigBee wireless module and flow sensor interface which receives flow rate signals, and a control output providing control to actuate multiple flow valves;

FIG. 11 is a block diagram showing an exemplary software architecture for the resource management and control system of the present invention, including specific drivers present on a ZigBee server, utilities operating on an application server, flash display interface operating on the display server, and a data center server operating MySQL, PHP, and Apache Web to run various device drivers and control processes, and the operation of the LINUX operating system;

FIG. 12 is an exemplary ZigBee link message format utilized by the resource management and control system of the present invention, including the frame field as designated to effect a message transmission from the electric node to the control station;

FIG. 13 is a flow chart of an exemplary data transfer through the resource management and control system of the present invention, from its initial creation in an electric node, through the ZigBee server, through the display server, to the central server, with a response message containing the updated information being returned to the display server;

FIG. 14 is a flow chart of an exemplary irrigation control process of the resource management and control system of the present invention in which a unique client folder is created within the central server, a profile for the specific client location is initiated, basic or advanced irrigation criteria are developed and calculated, and at the scheduled irrigation time, weather data is updated, and the irrigation program is autonomously executed;

FIG. 15 is an exemplary irrigation database table utilized by the resource management and control system of the present invention containing basic vegetation and environmental data (sunny/shady/turf/shrub), and historical weather information (minimum and maximum temperatures, radiation, and evaporation);

FIG. 16 is an irrigation table of the resource management and control system of the present invention summarizing actual data calculated and verified by the system of the present invention and providing consumption and cost histories;

FIG. 17 is a diagrammatical representation of the resource management and control system-of the present invention showing a typical household implementation, with an enlarged view of a typical user interface presented on the display server, and including various application programs, along with a set of specific operational icons;

FIG. 18 is an example of the typical user interface of FIG. 17 with the water icon accessed, and showing a gauge pair containing real-time water and energy consumption data, current cost and relationships to peer groups including neighboring users or neighborhood averages;

FIG. 19 is an example of the typical user interface of FIG. 17 with the thermostat icon accessed, and showing the current interior temperatures, and access buttons for the thermostat settings, zones, and schedule;

FIG. 20 is an example of the typical user interface of FIG. 17 with the calendar icon accessed, and showing the current temperature and time; and

FIG. 21 is an example of the typical user interface of FIG. 17 with the irrigation icon accessed, and showing the current schedule, a manual control button panel (hold, manual, and all zones), and access buttons for the irrigation settings, zones and schedule.

### DETAILED DESCRIPTION

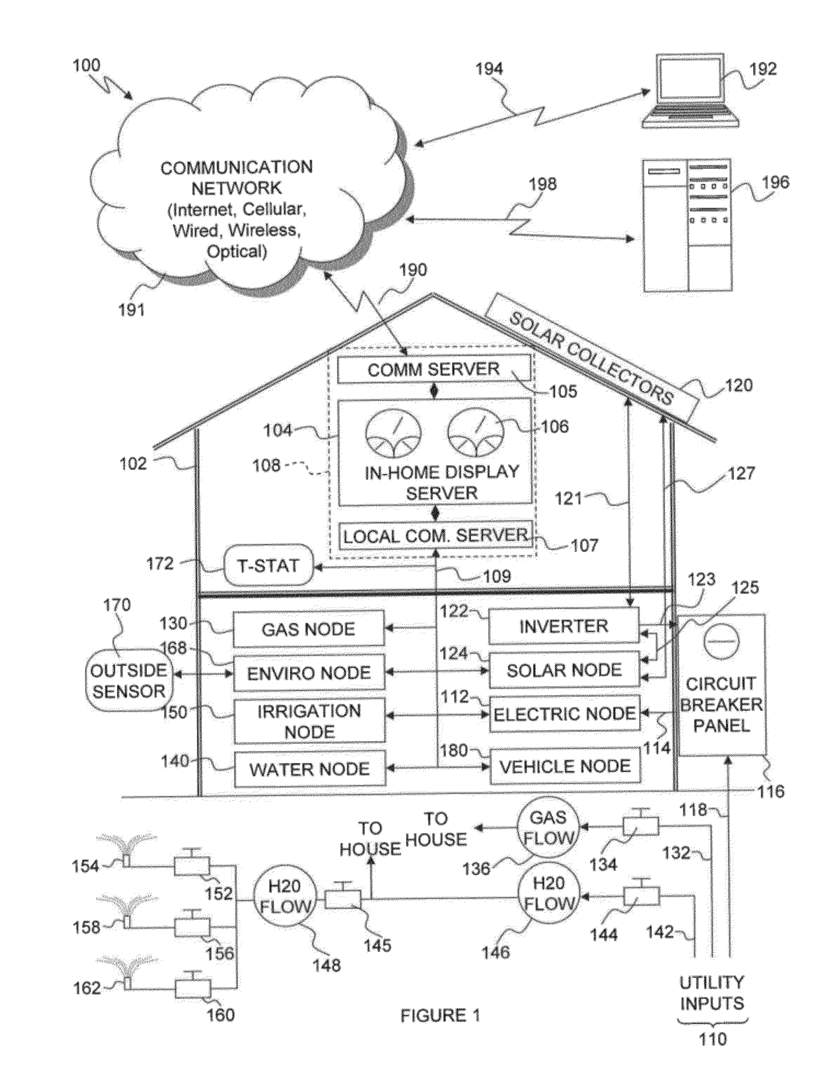

Referring initially to FIG. 1, a system-level diagram of the resource management and control system of the present invention is shown and generally designated 100. System 100 includes a user 101, such as a home 102. Home 102, in a preferred embodiment, includes a home display server 104 having an easily viewable display 106, in connection with a communication server 105 and a local communications server 107. Display server 104 and ZigBee, or local communications server 107 may be separate devices as shown, or may be operationally grouped together in a control station (shown in dashed lines). Further, the display server may consist of a collection of sub-processes present in both the home and in the data center that support the user interface display both in the home and on remote devices.

Communication server 105, in a preferred embodiment, facilitates the communications between the control station 108, and all external components of the system. The communication methods incorporated into communication server 105 include, but are not limited to, broadband wired communication using known or proprietary communication techniques, and broadband wireless communication using known communication techniques, such as cellular, GSM, CDMA, 3G and 4G wireless networks, and other wireless communication systems available.

Local communication server 107 is an intra-facility local area network and provides for a wired or wireless communication link 109. In a preferred embodiment, communication link 109 is consistent with the ZigBee communication standard. ZigBee is a specification for a suite of high level communication protocols using small, low-power digital radios based on the IEEE 802.15.4-2003 standard. In addition, ZigBee coordinators can also be provided to facilitate communication within the ZigBee communication link, and to interface to a wired communication system.

While this communication protocol is particularly well suited for the resource management and control system of the present invention, it is to be appreciated that other existing wireless, wired, and power line communication (PLC) communication protocols may be used alone or in combination, or a proprietary communication protocol may be incorporated herein without departing from the scope of the present invention.

Utility inputs 110 are supplied to home 102, and may include electricity, gas and water. Each of these utility inputs 110 is separately measured and monitored by the resource management and control system of the present invention. For instance, electric node 112 is in wireless communication with local communications server 107 through link 109, and in electrical connection 114 with circuit breaker panel 116. Electrical utility input 118 enters breaker panel 116 and is distributed throughout the house 102 as is standard in the industry. As will be described in greater detail below, the electric node 112 utilizes voltage and current sensors to monitor the condition and consumption of electrical energy, and relates this data through wireless communication link 109 to the local communications server 107.

Home 102 may be equipped with solar collectors 120. In a preferred embodiment, these solar collectors are solar panels of the photovoltaic type. A solar panel, also referred to as a photovoltaic module or photovoltaic panel, is a packaged interconnected assembly of solar cells, also known as photovoltaic cells. A solar panel is used as a component in a larger photovoltaic system to collect radiation energy from the sun and convert it to electricity for commercial and residential applications. Because a single solar panel can only produce a limited amount of power, many installations contain several panels to generate the increased levels of power.

Solar collector 120 is in electrical communication through connection 121 with an inverter 122 which converts the typically direct current (DC) voltage generated by the solar panel, to an alternating current (AC) voltage consistent with the electrical input 118 from utility inputs 110. Several inverters suitable for the present invention are available from a number of manufacturers, and provide an AC output voltage to circuit breaker panel 116 through connection 123. Typically, this AC output voltage is integrated into the panel 116 through an isolation breaker (not shown) to allow for isolating the solar collectors 120 and inverter 122 from the breaker panel 116.

Solar node 124 is in wireless communication with local communications server 107 through link 109, and monitors and controls the function of solar collectors 120 and inverter 122 through communication connections 127 and 125, respectively. This monitoring may include, but not be limited to, monitoring the electrical output (current and voltage) of collectors 120, monitoring the proper operation of inverter 122 and the condition of an isolation breaker if provided, and the isolation or electrical disconnection of the solar collectors 120 from circuit breaker panel 116.

Gas node 130 is in wireless communication with local communications server 107 through link 109, and monitors the rate of consumption of gas from gas input 132. Gas input 132 passes through a valve 134 and through gas flow meter 136 to the house 102. The control of the gas valve 134, and the monitoring of the gas flow meter 136 is accomplished by gas node 130, and the condition and results reported through wireless communication link 109 to local communications server 107.

Water node 140 is in wireless communication with local communications server 107 through link 109, and monitors the pressure, temperature and rate of consumption of water from water input 142. Water input 142 passes through valve 144, through primary flow meter 146, and branches off to the house 102, and through secondary valve 145 to irrigation equipment. The water to the irrigation equipment passes through secondary water flow meter 148 and to the irrigation circuits. This provides for an accurate measurement of the total water supplied (primary flow meter 146), and the portion of that water that is supplied to the irrigation system (secondary flow meter 148). For instance, water through secondary flow meter 148 can be supplied to valve 152 and irrigation zone 154, valve 156 and irrigation zone 158, and valve 160 and irrigation zone 162. By actuating valve 142, the water supply can be shut off entirely. Alternatively, by actuating valves 152, 156, and 162, the water supply to the irrigation system can be entirely shut off.

Irrigation node 150 is in wireless communication with local communications server 107 through link 109, and controls valves 152, 156, and 160. In a preferred embodiment, these valves provide control to irrigation zones 154, 158 and 162. It is to be appreciated that three (3) valves is merely exemplary, and that any number of irrigation zones, and associated valves, can be incorporated into the present invention. Irrigation node 150 receives instructions from control station 108 to open and close the valves according to a watering schedule described below in greater detail.

Environmental node 168 is in wireless communication with local communications server 107 through link 109, and may include an exterior located sensor array 170. For instance, in a preferred embodiment, interior-located environmental node 168 may monitor the temperature and humidity throughout the house 102, while the exterior-located sensor array 170 may provide exterior temperatures, humidity, radiation levels, or other energy-related measurements.

Thermostat 172 is in wireless communication with local communications server 107 through link 109, and in electrical connection with the heating and cooling systems of house 102. As is standard with typical heating and cooling installations, house 102 may be divided into various zones, and thermostat 172 may take measurements throughout various zones. Alternatively, multiple thermostats 172 may be utilized through house 102 to provide zone-specific temperature control. Also, house 102 may be equipped with multiple heating and cooling appliances, and each may be controlled by a separate thermostat 172.

Vehicle node 180 is in wireless communication with local communications server 107 through link 109, and may be provided to monitor the electrical consumption of a vehicle, such as an electric vehicle, or a charge-requiring hybrid.

Control station 108, including local communications server 107 and display server 106, is in communication with remote users and a central server. More specifically, control station 108, through communication link 190, passes through a communication network 191 and communication link 194 to remote user stations 192. Similarly, control station 108, through communication link 190, passes through communication network 191 and communication link 198 to a central server 196.

In a preferred embodiment, communication links 190, 191, 194 and 198 are web-based communication protocol passed over the Internet. It is to be appreciated, however, that other communication protocols and systems known in the art may be utilized without departing from the present invention.

As shown in this Figure, there is only one house 102, only one remote user station 192, and only one central server 196. It is to be appreciated that this depiction is merely for discussion purposes, and that any number of houses 102, any number of remote user stations 192, and perhaps multiple central servers 196 may be incorporated into the resource management and control system of the present invention.

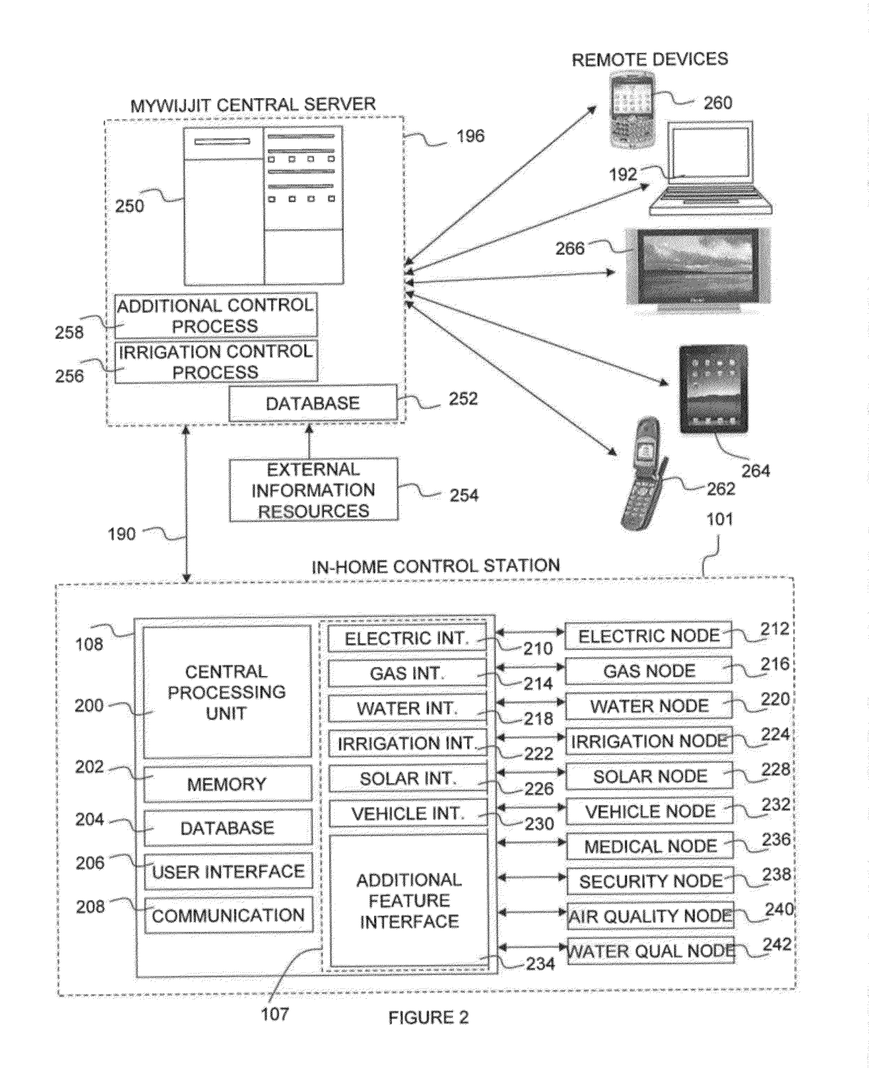

Referring now to FIG. 2, a block diagram of the resource management and control system of the present invention includes user 101 with a control station 108 having various components. As shown in this representation, control station 108 includes a central processing unit 200. In a preferred embodiment, central processing unit 200 is a dedicated computer system capable of performing all functions described herein. However, it is to be appreciated that other functionally capable processors, microprocessors, or microcontrollers may be utilized alone or in combination to achieve the functions of the present invention.

Central processing unit 200 may be equipped with an external memory 202, or such memory 202 may be integral to the processing unit 200. A resident database 204 includes sufficient memory storage to accommodate all locally-stored historical, environmental, and empirical data necessary to operate the resource management and control system of the present invention.

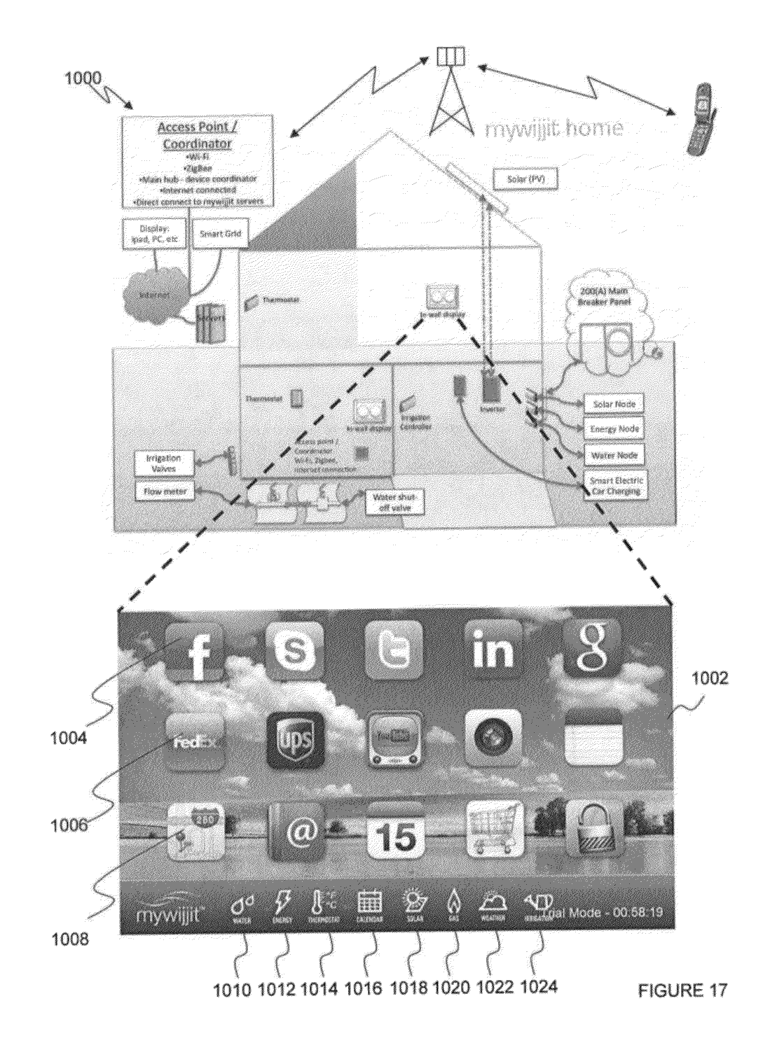

User interface 206 is integrated with central processing unit 200 to provide a user within house 102 with an easy-to-understand graphic display that yields real-time data regarding the resource management and control system of the present invention. As will be shown in conjunction with FIGS. 17 through 21, the user interface facilitates the easy operation of all systems within house 102, and up-to-the-minute details of energy consumption, costs, and savings.

Communication module 208 provides the communication between control station 108 and central server 196 through communication link 190. Central server 196 includes one or more computer systems 250 networked together to communicate and control multiple control stations 108. It is important to note that the resource management and control system of the present invention is completely scalable, and can be enlarged to accommodate virtually an unlimited number of users 101. Indeed, this scalability is a critical feature of the present invention in that it provides large community homebuilders, or existing neighborhoods, with the ability to aggregate their conservation efforts, resulting in increased savings for all.

Within control station 108 are a number of interfaces. In a preferred embodiment, each node is in communication with its particular interface. While it is appreciated that the communication between each node and the control station will be handled by the local communications server 107, an interface for each node is provided. For instance, electrical interface 210 corresponds to electric node 212, gas interface 214 corresponds to gas node 216, water interface corresponds to water node 220, irrigation interface corresponds to irrigation node 222, solar interface 226 corresponds to solar node 228, and vehicle interface corresponds to vehicle node 232. Additionally, an additional feature interface 234 may correspond to additional optional nodes, such as medical node 236, security node 238, air quality node 240 and water quality node 242. These optional nodes are provided to enhance the functionality of the resource management and control system of the present invention.

Medical node 236 provides personnel within house 102 the ability to quickly summon medical assistance, or in the event there are medical devices in operation within the house 102, to monitor the proper operation of those devices and to report any malfunction or servicing needs.

Security node 238 serves as a security system for the house 102. In a preferred embodiment, security node 238 may include traditional security components, such as motion sensors, door and window contact switches, and fire or smoke detectors. Operation of the security system would be achieved through user interface 206, and would be monitored by central server 196.

Air quality node 240 may include an array of sensors, such as oxygen, carbon dioxide, carbon monoxide, and particulate sensors. In a preferred embodiment, air quality node 240 may also be configured to provide input to control station 108 to increase the introduction of fresh-air into home 102 to alleviate low oxygen, high carbon dioxide or carbon monoxide readings, or to lower the introduction of fresh-air when it contains increased levels of particulate matter.

Returning to central server 196, a database 252 is provided in communication with computer system 250 and is of sufficient size and accessibility to provide storage for all historical, environmental and empirical data for the resource management and control system of the present invention. In addition to database 252, external information resources 254 are provided. In a preferred embodiment, these information resources can include, but not be limited to, global, real-time environmental data from such sources as local, state, and national weather forecasts, and historical weather data; utility company energy rate tables and comparative usage data; user account data with past charges for water, electric and gas consumption; and user real-time geographical location from location services.

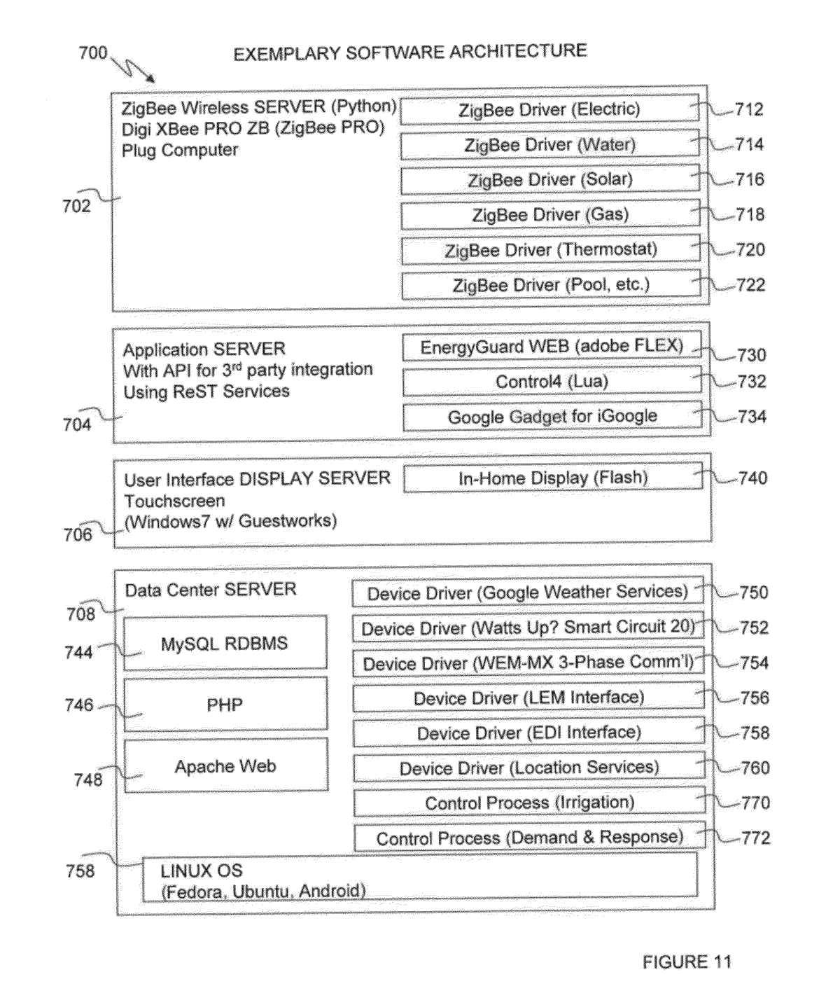

Central server 196 is shown and includes autonomous control processes including, for example, an Irrigation Control Process 256. As will be shown in FIGS. 11, 14, 15 and 16, an autonomous irrigation control process can achieve the best watering performance for the minimum consumption of water, independent of the user implementing behavioral changes to improve consumption practices.

Central server 196 is shown in communication with multiple remote devices. For instance, remote user station 192 is shown and depicts a portable computer, or laptop computer. Remote user station 192 may be virtually any internet-capable computing device, including but not limited to laptop computers, portable computers, desktop computers, iPhone™, Google Powermeter™, Android™, Automation systems (AMX, CONTROL4, Crestron, HAI), iPad™ web-enabled television, cable/satellite/Tivo interfaces, and reduced instruction set computers designed specifically for remote access to the resource management and control system of the present invention. Along with the remote user station 192, a personal computing device, such as a smartphone 260 may be used in conjunction with the present invention. Other devices may be utilized to access and interface with the present invention. For instance, a standard cellular telephone 262, tablet computer (iPad™) 264, or television 266 may be used to access and control the present invention.

Control of the resource management and control system of the present invention using these various remote devices may be accomplished through one or more of the following: automated voice based telephonic interfaces, text-messaging interfaces, web-based interfaces, or any other communication protocol known in the art that provides a sufficient user interface.

Many of the components described in conjunction with FIG. 2 have been described as separate functional units for discussion purposes. It is to be appreciated that such separation is merely for discussion purposes, and that the combination or bundling of one or more of these components may be made without departing from the scope of the present invention. Moreover, the various interfaces which have been discussed (electric 210, gas 214, water 218, irrigation 222, solar 226 and vehicle 230) may be accomplished using software (e.g. operational instructions) within central processing unit 200 of control station 108 to decode and create the wireless messaging between the various nodes and the local communications server 107 (shown in dashed lines).

A key benefit of utilizing the ZigBee communication standard is the ability to establish a mesh network between the various nodes of a user 101. For instance, referring back to FIG. 1, the irrigation node 150 may be located a long distance from the control station 108 and local communications server 107 such that a wireless signal that is directed to the irrigation node 150 may not be received. In such an instance, a different node, such as the solar node 124, may receive the message directed to the irrigation node 150, and then re-transmit that signal to the irrigation node 150. This results in a very robust communication network that is easily installed without the typical concerns of radio-frequency interference or signal obstructions, and provides an instantly expandable system.

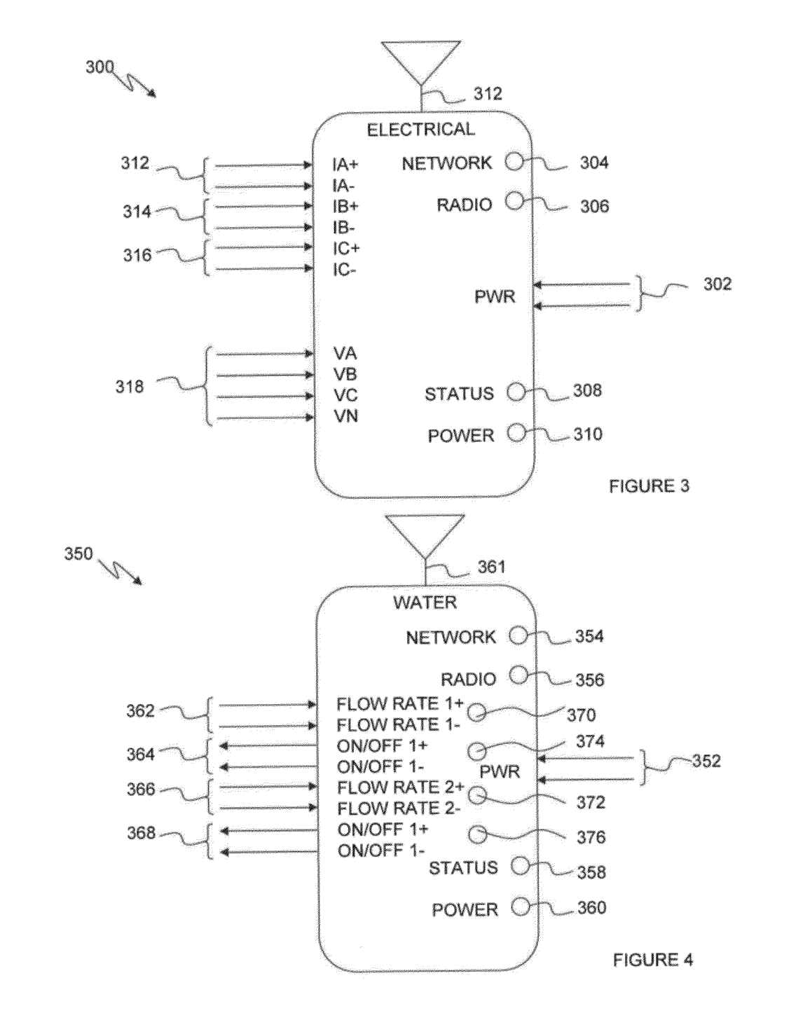

Referring now to FIG. 3, a diagrammatic representation of an electrical node module is shown and generally designated 300. Electrical node 300 includes a power input 302, and a number of status light emitting diodes (LEDs), such as network confirmation LED 304, radio operation confirmation LED 306, status indicator LED 308, and power indicator LED 310. An antenna 311 may be external to the chassis, or contained or embedded within the chassis, or formed on a circuit board within the chassis.

The function of the various status LEDs are consistent from node to node within the resource management and control system 100 of the present invention. The selective illumination of the various status LEDs can be programmed to provide instantaneous visual indication of the proper operation of the node. In a preferred embodiment, Power LED 310 is on when power supply is connected and active. Network LED 304 is driven by the wireless communication circuit within the node, and will flash differently depending on the state of the module to the network. Similarly, the radio LED 306, also driven by the wireless communication circuit, allows the signal strength indication to be visually observed. The status LED 308 is controlled by the firmware within the node and its function in the energy module may be adjusted during manufacturing. In a preferred embodiment, upon powering up the node, and after passing any built-in self-diagnostics, the status LED 308 will give 3, ½-second pulses to indicate that the system appears to be working normally. If any system problems are determined, the status LED 308 should continuously flash an error code indicative of the problem. An example of error code ‘2’ could be 2 flashes followed by an off interval period, then repeating. If the node is operating normally, the status LED 308 is off unless some anomaly is noted. The illumination of the LED status indicators is merely exemplary, and can be changed without departing from the present invention.

Electrical node 300 includes a number of current measurement and voltage measurement inputs to sense the electrical energy being utilized by the house 102. In a preferred embodiment, electrical node 300 is capable of sensing current and voltage for three independent AC sources. It may be that each voltage and current represents different phases of multi-phased power sources, or each may be independent of the others. For instance, differential current inputs A 312, B 314 and C 316 receive current sensing of the electrical supply 118 from utility 110.

In a preferred embodiment, the current sensing is achieved using an inductive sensor, such as a Rogowski coil. A Rogowski coil is an electrical device for measuring alternating current (AC) or high speed current pulses. It consists of a helical coil of wire with the lead from one end returning through the centre of the coil to the other end, so that both terminals are at the same end of the coil. The whole assembly is then wrapped around the straight conductor whose current is to be measured. Since the voltage that is induced in the coil is proportional to the rate of change (derivative) of current in the straight conductor, the output of the Rogowski coil is usually connected to an electrical (or electronic) integrator circuit in order to provide an output signal that is proportional to current.

One advantage of a Rogowski coil over other types of current transformers is that it can be manufactured open-ended and flexible, allowing it to be wrapped around a live conductor without disturbing it. Because a Rogowski coil has an air core rather than an iron core, it has a low inductance and can respond to fast-changing currents. Also, because it has no iron core to saturate, it is highly linear even when subjected to large currents and is largely immune to electromagnetic interference.

The Rogowski coil incorporated in the present invention provides a convenient and easy to install solution for current measurement as there are no rigid ferrite cores like those used in competing inductive current sensors. Instead, the flexible conductor is secured around a current-carrying wire, and the current sensitivity is sufficient to provide accurate current measurements across a broad range of currents. While the Rogowski coil as described herein is a preferred embodiment, the incorporation of other current sensing devices in the present invention is fully contemplated, including but not limited to clamp-on current sensing devices.

Three voltage inputs and a neutral connection 318 are provided to sense three separate AC voltage levels. The three AC voltages share the same neutral potential and are labeled VA, VB, VC, and VN. The inputs are identical in design and generic, thus allowing the firmware to determine the function of each input. In a preferred installation, voltage VA corresponds to current IA (+/−) 312, voltage VB corresponds to current 1B (+/−) 314 and voltage VC corresponds to current IC (+/−) 316. In a typical home installation VA and VB would be used to measure the two-phase mains voltage entering the house and VC would be used to monitor an alternative energy source of power such as wind or photovoltaic panels. Accordingly, by utilizing the instantaneous current and voltage measurements for A, B and C, the power associated with each can be determined using the simplified equation Power=Current×Voltage (P=IV). The algorithms actually implemented take into consideration other factors, and this simplified equation is merely for discussion purposes, and in no way intended to limit the scope of the present invention.

Referring now to FIG. 4, a diagrammatic representation of a water node module is shown and generally designated 350. Water node 350 includes a power input 352, and a number of status light emitting diodes (LEDs), such as network confirmation LED 354, radio operation confirmation LED 356, status indicator LED 358, and power indicator LED 360. An antenna 361 may be external to the chassis, or contained or embedded within the chassis, or formed on a circuit board within the chassis.

Water node 350 includes a pair of differential flow rate input (FLOW RATE 1+/−) 362 and (FLOW RATE 2+/−) 366 to receive flow rate signals from flow rate sensors 146 and 148 (shown in FIG. 1), and a pair of control outputs (ON/OFF 1+/−) 364 and (ON/OFF 2+/−) 368 to control valves 144 and 145 (shown in FIG. 1).

Separate flow rate status LEDs 370 and 372 provide a visual indication of any measurable water flow. For instance, FLOW A LED 370 is on and flashing when flow is detected at Input A. 362, and FLOW B LED 372 is on and flashing when flow is detected at Input B 366. Control output status LEDs 374 and 376 provide a visual indication of the ON/Off state of the control output. For instance, OUTPUT LEDs 374 and 376 are on when outputs 364 and 368 are in the ON configuration.

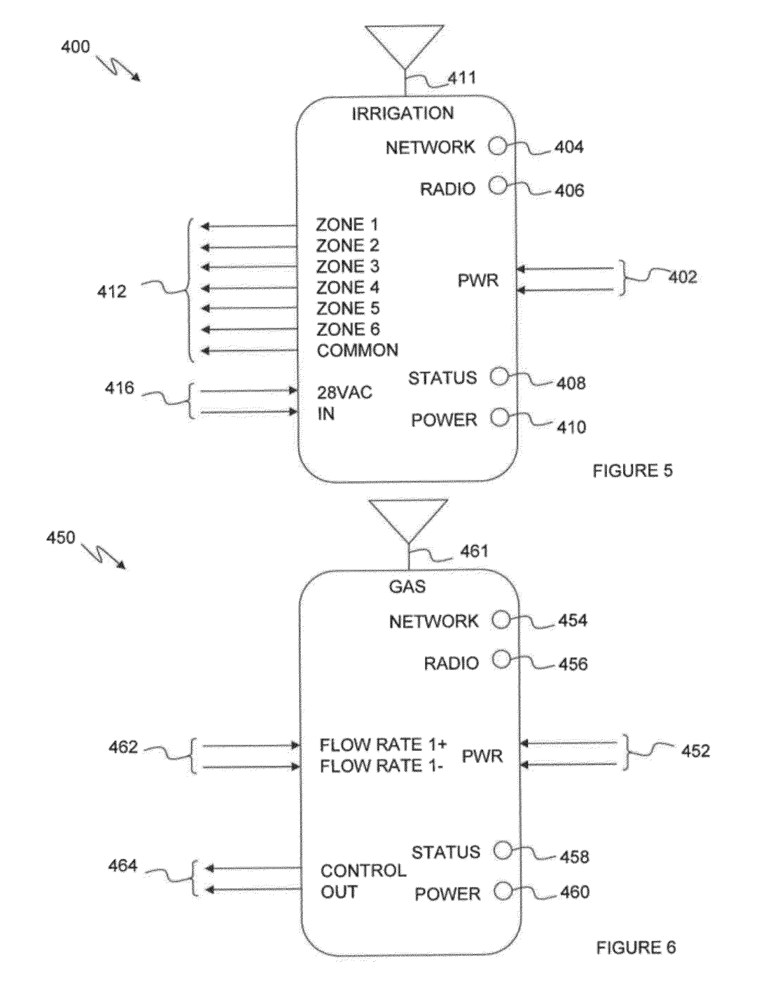

FIG. 5 is a diagrammatic representation of an irrigation node module generally designated 400. Irrigation node 400 includes a power input 402, and a number of status light emitting diodes (LEDs), such as network confirmation LED 404, radio operation confirmation LED 406, status indicator LED 408, and power indicator LED 410. An antenna 411 may be external to the chassis, or contained or embedded within the chassis, or formed on a circuit board within the chassis.

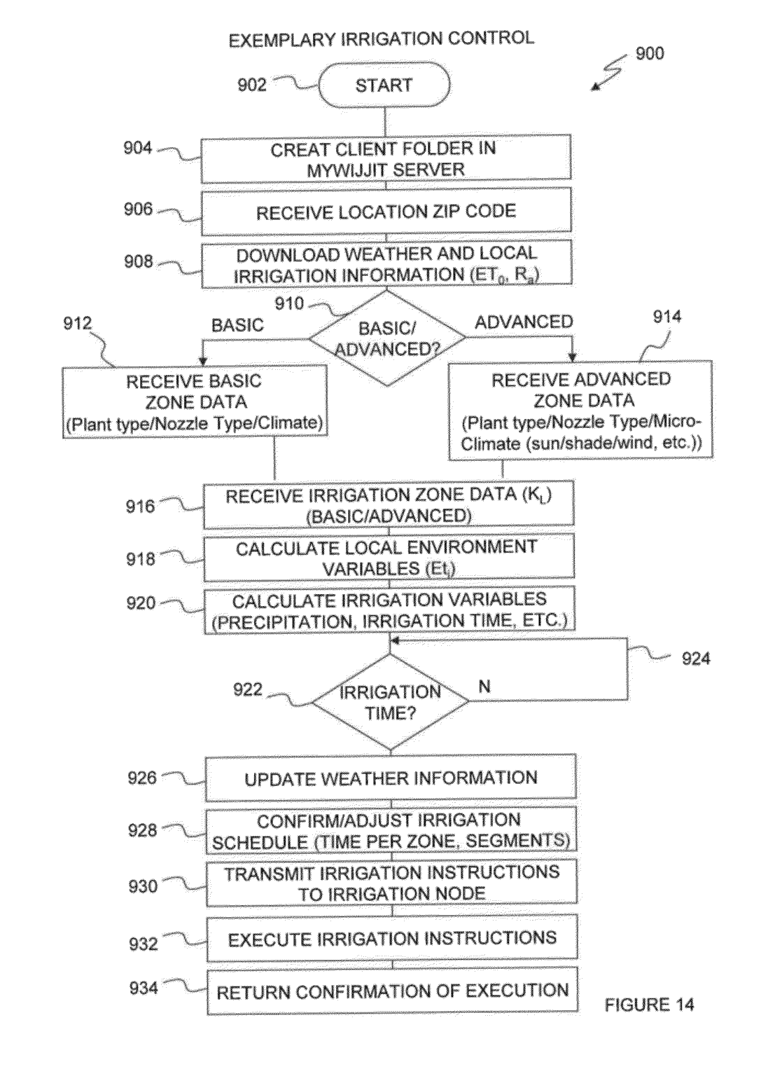

Irrigation node 400 includes a 28 VAC input 416 which is used to drive various irrigation zones through irrigation zone control outputs 412. Specifically, input 416 receives a voltage suitable for driving typical irrigation control valves (see 152, 156, and 160 of FIG. 1). This voltage on input 416 is selectively provided to zone control outputs 412 according to a determined irrigation schedule. This scheduling will be described in greater detail in conjunction with FIGS. 14-16.

As an alternative to providing irrigation node 400 with input voltages 416, node 400 can derive the voltages necessary to control irrigation zone control outputs 412 from power input 402.

Referring now to FIG. 6, a diagrammatic representation of a gas node module is shown and generally designated 450. Gas node 450 includes a power input 452, and a number of status light emitting diodes (LEDs), such as network confirmation LED 454, radio operation confirmation LED 456, status indicator LED 458, and power indicator LED 460. An antenna 461 may be external to the chassis, or contained or embedded within the chassis, or formed on a circuit board within the chassis.

Gas node 450 includes a single differential flow rate input 462 designed to receive a flow rate signal from gas flow meter 136 (shown in FIG. 1). In a preferred embodiment, a control output 464 is provided to a gas valve, such as valve 134 (shown in FIG. 1). In the event that a gas leak is detected, system 100 can interrupt the flow of gas in supply 132 from utility 110 into the house 102.

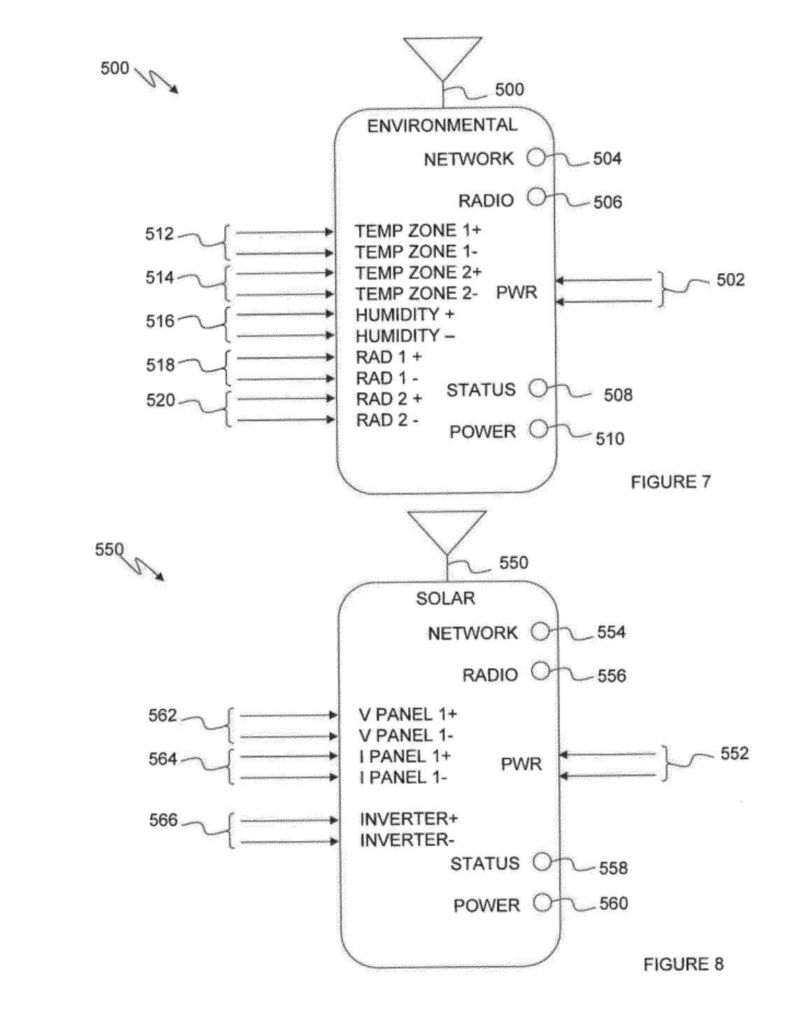

FIG. 7 is a diagrammatic representation of an environmental node module generally designated 500. Environmental node 500 includes a power input 502, and a number of status light emitting diodes (LEDs), such as network confirmation LED 504, radio operation confirmation LED 506, status indicator LED 508, and power indicator LED 510. An antenna 511 may be external to the chassis, or contained or embedded within the chassis, or formed on a circuit board within the chassis.

Environmental node 500 includes three (3) differential temperature zone inputs 512 and 514, differential humidity input 516, and two (2) differential radiation level inputs 518 and 520. As shown in FIG. 1, the environmental node 500 may include an exterior sensing unit 170 that provides input related to current external conditions. These various inputs can provide the resource management and control system of the present invention with real-time local environmental information that can be utilized to optimize energy use, and realize the largest savings possible.

Referring now to FIG. 8, a diagrammatic representation of a solar node module is shown and generally designated 550. Solar node 550 includes a power input 552, and a number of status light emitting diodes (LEDs), such as network confirmation LED 554, radio operation confirmation LED 556, status indicator LED 558, and power indicator LED 550. An antenna 561 may be external to the chassis, or contained or embedded within the chassis, or formed on a circuit board within the chassis.

Solar node 550, in a preferred embodiment, includes at least one pair of differential voltage and current inputs. For instance, differential voltage input 562 and differential current input 564 provide basic instantaneous power production measurements for a solar collector 120. Solar node 550 may also include an interface 566 for the inverter connected with solar collector 120, to receive condition data concerning the proper operation and power production of the solar collector 120.

While a single voltage and current input 562 and 564 are shown on solar node 550, it is to be appreciated that the node may be equipped with multiple voltage and current measurement inputs to accommodate a system user 101 having multiple solar collectors 120.

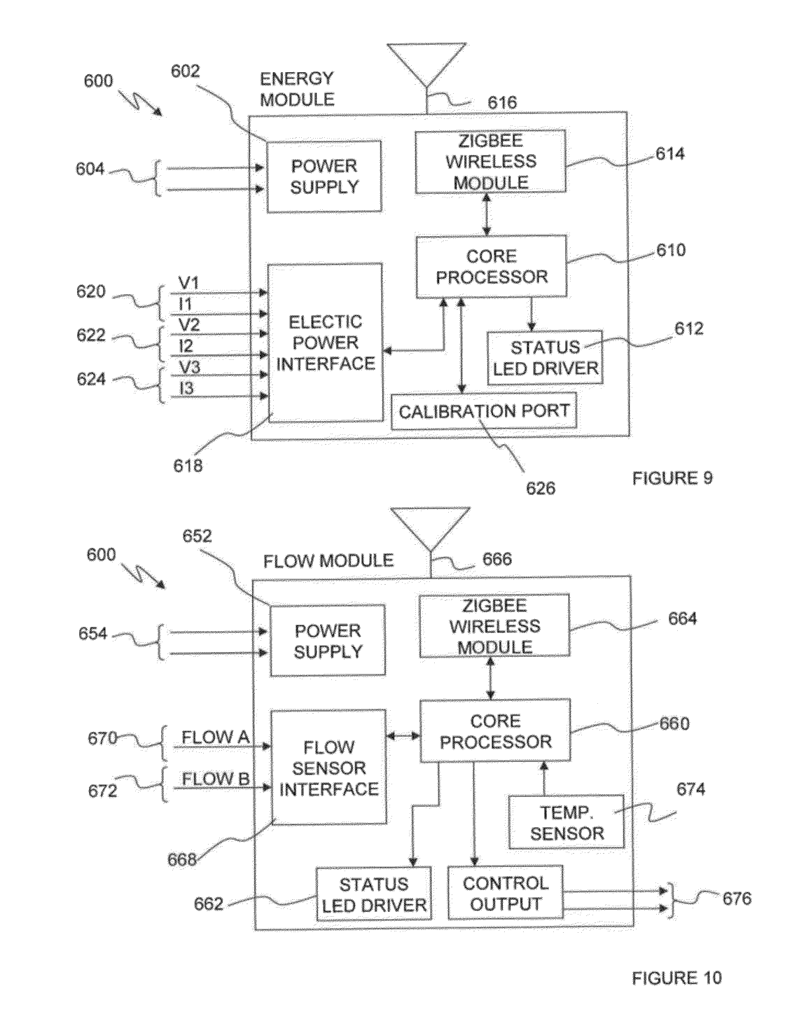

FIG. 9 is a block diagram of the circuitry of a typical energy module and generally designated 600. Block diagram 600 includes a power supply 602 having an input 604, and which generates all voltage levels required for operation of the energy module. A core processor 610 provides digital processing to the energy module. In a preferred embodiment, core processor 610 is a microcontroller having onboard program and dynamic storage memory, such as the PIC18Fxxxx family of microcontrollers. It is to be appreciated that the incorporation of such microcontrollers into the modules of the resource management and control system of the present invention is merely exemplary of a preferred embodiment, and no limitation as to the selection or incorporation of alternatively functioning computing devices is intended.

Status LED driver 612 receives input from core processor 610 to illuminate the status LEDs (304, 306, 308 and 310 shown in FIG. 3) to provide visual indicators of the node's operational state. Core processor also communicates with wireless module 614. As described above, in a preferred embodiment, module 614 is a ZigBee communication module and establishes a bidirectional mesh communication network throughout house 102. Because each ZigBee implementation is established with a unique serial number and identifier, it is capable of distinguishing any house 102 from any neighboring house, thereby providing security and reliability in operation. It is to be appreciated that incorporation of a ZigBee communication module into the resource management and control system of the present invention is merely exemplary of a preferred embodiment, and no limitation as to the selection or incorporation of alternative functionally equivalent or similar communication interfaces such as PLC is intended.

Electrical power interface 618 includes three paired voltage and current inputs 620, 622, and 624 which receive voltage and current levels from AC power sources such as different phases of multi-phase power to a property. In a preferred embodiment, electrical power interface 618 is a high accuracy, 3-phase electrical energy measurement IC with a serial interface and two pulse outputs. One suitable device is the Analog Devices ADE7758 which incorporates second-order Σ-Δ analog to digital converters (ADCs), a digital integrator, reference circuitry, a temperature sensor, and all the signal processing required to perform active, reactive, and apparent energy measurement and RMS calculations. The data output of electric power interface 618 is provided to core processor 610 to be manipulated and transmitted through the wireless module 614.

A variety of signal conditioning circuits can be incorporated into the electrical node of the present invention, and are fully contemplated herein. Such signal conditioning is well known in the art, and intended to remove spurious noise and signal glitches that would otherwise contribute to erroneous measurements.

In addition to the three phase electrical voltage inputs 620, 622, and 624, it is possible to detect the electrical voltage levels from the supply voltage inputs 302. Using this approach, only a single electrical input connection is required to sense voltage levels within the system.

In order to easily manufacture the electrical node 600, it may be equipped with one or more factory calibration port(s) 626. Due to the unique nature of the electrical node and the accuracy requirement, provisions for the factory calibration of the node have been made. To that end, the PIC microcontroller selected as a preferred embodiment has two distinct communication ports. One port (TX1/RX1) has been dedicated to the transmission of radio data to wireless module 614, and a second port (TX2/RX2) is to be used exclusively for calibration purposes.

Connection to the processor calibration port is available and uses standard logic-levels. To connect this input to a computer port, either an RS-232 or USB adapter circuit must be used as part of the test setup. Additionally, to aid in calibration of the module, direct connection to the electric power interface output is available.

Referring now to FIG. 10, a block diagram of the circuitry of a typical flow module is shown and generally designated 650. Block diagram 650 includes a power supply 652 having an input 654, and which generates all voltage levels required for operation of the flow module. A core processor 660 provides digital processing to the flow module. In a preferred embodiment, core processor 610 is a microcontroller having onboard program and dynamic storage memory, such as the PIC18Fxxxx family of microcontrollers. It is to be appreciated that the incorporation of such microcontrollers into the modules of the resource management and control system of the present invention is merely exemplary of a preferred embodiment, and no limitation as to the selection or incorporation of alternatively functioning computing devices is intended.

Status LED driver 662 receives input from core processor 660 to illuminate the status LEDs (such as 354, 356, 358, 360, 370, 372, 374 and 376 shown in FIG. 4) to provide visual indicators of the node's operational state. Core processor 660 also communicates with wireless module 664. As described above, in a preferred embodiment, module 664 is a ZigBee communication module and establishes a bidirectional mesh communication network with other nodes throughout house 102.

Flow sensor interface 668 is in electrical communication with core processor 660, and includes a pair of flow inputs 670 and 672. These inputs allow for the measurement of flow rate at two separate locations in the house 102, such as incoming mains and irrigation (flow meters 146 and 148 of FIG. 1). The flow input A 670, in a preferred embodiment, is specifically dedicated to CST or similar digital flow rate sensors. This input is primarily intended to connect to a 2-wire, pulse output, flow rate sensor, such as the CST type through a low pass filter (not shown). These sensors allow the measurement of flow rate by detecting a frequency by simply counting pulses over a known time interval and/or resolution of an edge transition

Flow Input B 672 may be used for either CST type flow rate sensors or totalizer type, contact closure inputs. Input 672 is a generalized, auxiliary input but primarily intended to connect to a contact-closure, pulse-per-volume output, water meter type sensor. In the contact-closure mode, the input hardware includes a low-pass filter network to suppress contact bounce and spurious noise impulses.

Flow measurements are determined in different manners depending on the type of sensor utilized. For instance, pulse output flow rate sensors exhibit a linear relationship between the actual flow rate and the pulse rate typically characterized by the following equation: GPM=K(Fs+Fo) where: GPM=flow rate in Gallons Per Minute; K=flow constant (GPM/Hz); Fs=sensor pulse frequency, and Fo=offset frequency.

For the CST series of sensors, the following calibration data applies:

| Size | K | Offset |
|---|---|---|
| 1 | 0.320 | 0.022 |
| 1½ | 0.650 | 0.750 |
| 2 | 1.192 | 0.938 |

During setup of the system 100, the user utilizes the user interface to select the water supply pipe sizes to the house 102, such as selection of pipe sizes from standard pipe diameters (1″, 1.5″ and 2″). With this information available, the calculation of the flow rate through the flow meter 146 and 148 can be made.

To measure frequency, core processor 660 counts the number of pulses accumulated in 1 second, and filters the results using either an DR or FIR filter approach with a time constant of around 5 to 10 seconds. This approach places very minimal burden on the processor 660 and has worked well,

A control output 676 is provided and includes a 40 volt, 1 amp, solid-state relay output capable of actuating typical 24 VAC irrigation valves. Also, a temperature sensor 674 is provided within the flow module. In a preferred embodiment, temperature sensor 674 includes a thermistor on the module's printed circuit board which allows the measurement of the module temperature. Assuming that this sensor is exposed to the exterior ambient environment, this feature would be useful for potential freeze alerts, and can be used to interrupt the flow of water into the house 102 in the event of a pipe failure.

Referring now to FIG. 11, a block diagram showing an exemplary software architecture for the resource management and control system of the present invention is generally designated 700. Architecture 700 includes a wireless server 702, application server 704, user interface display server 706 and a data center server 708.

Wireless server 702 runs the ZigBee Pro operating system, and includes a electric node driver 712, a water node driver 714, a solar node driver 716, a gas node driver 718, a thermostat driver 720, and additional wireless interface drivers 722 as needed (such as for a pool, medical, security, etc.). In a preferred embodiment, wireless server 702 operates on a plug computer.

Application server 704 runs API with third-party integration, using the ReST Services™. Within the application server, the ENERGY GUARD Web application utilizing Adobe FLEX™ 730 runs and Control4 (Lua)™ 732 algorithms are incorporated, Also, GOOGLE GADGET™ for iGoogle 734 is incorporated to provide an interface between the application server and various remote user devices.

User interface display server 706 utilizes a touchscreen interface running Windows7™ with Guestworks™, and a proprietary in-home display program that displays the user interface display and receives tactile selections from the user.

Data center server 708 utilizes the MySQL RDMBS sequel server relational database management system 744. MySQL provides multiple users with access to a number of databases, such as is required when the resource management and control system of the present invention is running simultaneously on multiple users 101.

Also running within data center server 708 is a Hypertext Preprocessor (PHP). PHP is a widely used, general-purpose scripting language that was originally designed for web development to produce dynamic web pages. For this purpose, PHP code is embedded into the HTML source document and interpreted by a web server with a PHP processor module, which generates the web page document and facilitates the creation of web-based data for use throughout the resource management and control system of the present invention.

Apache Web HTTP server application 748 also runs within the data center server, and provides web interface for the system. Various device drivers are also resident on the data center server. For example, Google Weather Services 750, Watts Up? Smart Circuit 20 752, WEM-MX 3-Phase Commercial 754, and LEM interface 756 are utilized in obtaining weather data, and determining energy rates. Device drivers that interface to the user billing information over EDI 758 and interface to Location Services 760 available from cellular network operators are also shown. Further, the Data center server 708 further includes autonomous resource optimization process, such as the preferred embodiment of an Irrigation Control Process 770 is shown. Finally, Data center server 708 also utilizes the LINUX operating system 758, and interfaces with Fedora, Ubuntu, and Android.

The various combinations and allocations of software operating on the various servers as described in conjunction with FIG. 11 are merely exemplary of a preferred embodiment. It is to be appreciated that the relocation of software modules within the architecture 700 is fully contemplated, and that the selection or substitution of software modules with similarly-function software is also fully contemplated without departing from the scope of the present invention.

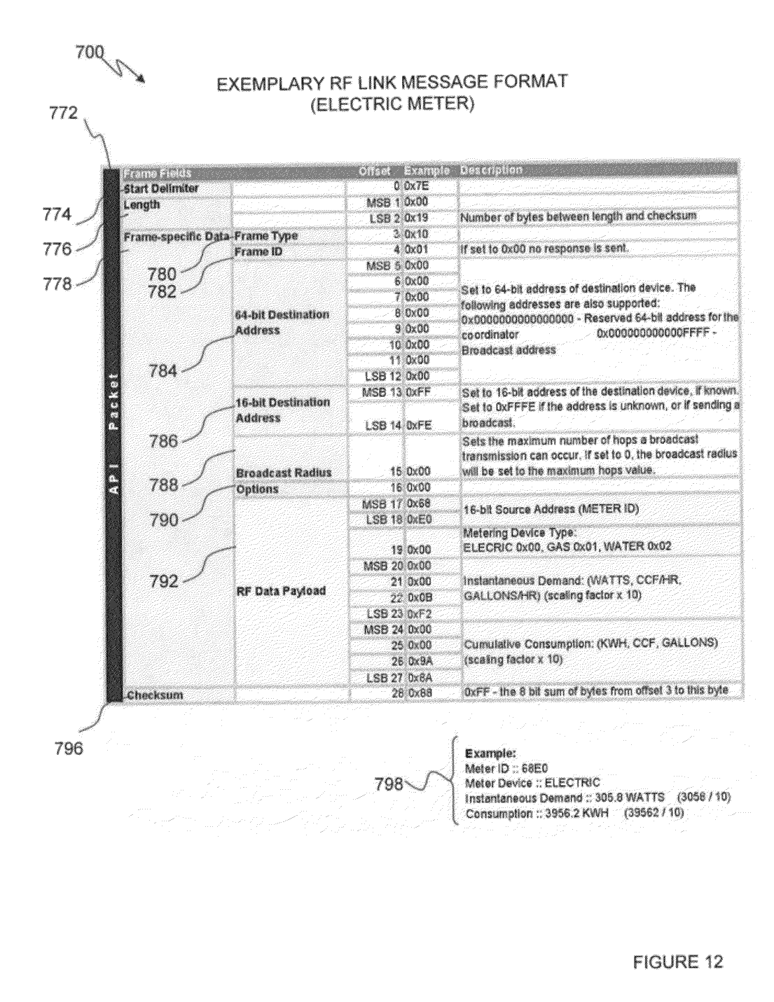

FIG. 12 is an exemplary wireless message format generally designated 770. Message 770 includes standard API packet 772 containing various ZigBee frame fields. In this embodiment, the message format begins with a start delimiter 774, and sets forth a message length 776. The frame-specific data 778 includes such variables as frame type 780, frame ID 782, 64-bit destination address 784, 16 bit destination address 786, broadcast radius 788, any available message options 790, and the RF data payload 792. In the present example, the RF data payload identifies the meter device as ELECTRIC, and the instantaneous demand is 305.8 Watts, and consumption is 3956.2 KWH. The message concludes with a checksum 796.

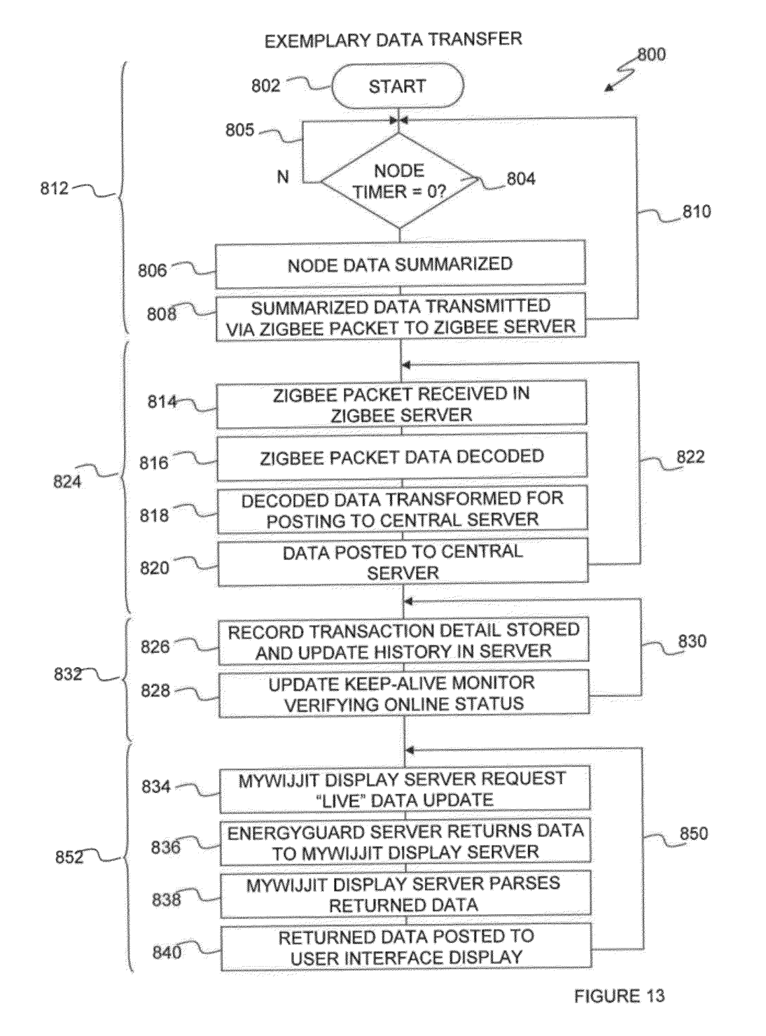

The message format set forth in FIG. 12 is exemplary of a standard ZigBee communication. By utilizing the specific 64 bit and 16 bit addresses 784 and 786, a specific house 102, and a specific node within the house are identified. The broadcast radius 788 sets out the number of message “hops” that can be made with a single message between multiple ZigBee transceivers. Referring now to FIG. 13, a flow chart of an exemplary data transfer from is shown and generally designated 800. Flow chart 800 begins in step 802, and a first decision is made in step 804 to determine if the node timer has expired. The node timer is established to establish the rate at which the node self-reports to the local communications server 107. If the timer has not expired, the system waits in loop 805. Upon expiration of the node timer, the node data is summarized in step 806. As an example, the energy node embedded processor timer is pre-set to transmit data every 15 seconds.

In step 808, the summarized data is transmitted via ZigBee packet data in the message format as set forth in FIG. 12, namely, the ZigBee API Packet Frame using Digi XBee PRO radio API mode, and transmits data such as a unique Meter ID, the metering device type, its instantaneous demand (Watts), and its cumulative consumption (kWh). The summarized data is contained within the RF data payload section 792 of the API packet message 772. Steps designated by grouping 812 occur in the specific node.

In step 814, the ZigBee packet is received in the wireless server using a USB XStick ZigBee radio. The serial ZigBee radio packet data is decoded in step 816 using the ZigBee server application Python running on a Linux operating system. The decoded data is transformed for posting to the central sever in step 818 using Fedora Linux in the secure data center). The transformed data is then posted to the central server in step 820 using a remote MySQL call to calculate the history stored procedure in the data center. Flow chart 800 returns to step 814 to receive any subsequent messages from the node. Steps designated by grouping 824 occur in the wireless server.

In step 826, the record transaction data from the node is stored and the history is updated in the central server. Central server updates the keep-alive monitor and verifies the online status of the user in step 828. For example, MySQL procedures populate the last read, transaction detail and history, plus a keep-alive heartbeat is updated to report ONLINE status. Also, minute processes run to look for event programming logic engine changes, hourly processes run to update the weather data used for data normalization, and nightly processes run to compress/purge data, update historical buckets (in compliance with CALGreen A5.204.2.1 data storage requirements). Flow chart 800 returns to step 826 to receive any subsequent messages from the wireless server. Steps designated by grouping 832 occur in the central server.

At pre-determined intervals, such as every 15 seconds, or upon demand, the display server requests “live” update data from the central server in step 834 using Web Service call. The central server returns current operational data to the display server in step 836, and the display server parses this data in preparation for posting in step 838. The parsed returned data is posted to the user interface on the display server in step 840. Specifically, Web Service returns data to an Adobe Flash Application to parser on receive using the RESTful data services, and the parsed data updated on screen. Flow chart 800 returns to step 834 in anticipation of receiving a request for a subsequent “live” update. Steps designated by grouping 852 occur in the display server.

Flow chart 800 depicts an exemplary data transfer and handling of a message from its initial creation in an electric node, through the wireless server, through the central server, and a response message containing the updated information being returned to the display server. The specific locations of these functional steps are merely exemplary of a preferred embodiment, and it is to be appreciated that these steps can be performed throughout the resource management and control system of the present invention without departing from the spirit of the invention.

Referring now to FIG. 14, a flow chart of an exemplary irrigation control process is shown and generally designated 900. Flow chart 900 begins with start step 902, and in step 904 a unique client folder is created within the central server. The central server receives the client location zip code in step 906, and downloads weather and local irrigation information in step 908. Utilizing the zip code obtained in step 906, the central server creates a profile for the specific client location, and can include standard evapotranspiration ratings, and known radiation averages in the region.

The user can then select in step 910 to use a basic or advanced irrigation criteria. For instance, if basic criteria is selected, in step 912, the user enters basic information regarding the house 102 and its surroundings. For instance, general plant types, nozzle types, and overall climate conditions are entered. Alternatively, the user enters advanced information which includes specific plant types, nozzle types, soil types, microclimate characteristics, sloped or flat areas, and other characteristics used to determine optimum irrigation needs.

The user provided irrigation zone data (K_{L}) is received in step 916, and the specific local environmental variables, such as the specific evapotranspiration levels, are calculated in step 918. Next, irrigation variables such as precipitation history, required irrigation schedules, segmentation, and irrigation start times are calculated in step 920.

Once the calculation of the irrigation schedule has been made, the system awaits the specified irrigation time in step 922, and wait loop 924. Once the irrigation time arrives in step 922, the current weather information is updated in step 926, and the irrigation schedule is confirmed or adjusted in accordance with the newly obtained weather information in step 928. The adjusted irrigation schedule is implemented and irrigation instruction signals are transmitted to the irrigation node in step 930. Each of the irrigation instructions is executed in step 932, and once completed, a confirmation of execution including actual watering time is returned in step 934.

The specific steps set forth in the exemplary irrigation control flow chart 900 are merely exemplary of a preferred embodiment. A great deal of information can be utilized in optimizing the irrigation instructions for providing adequate irrigation, with minimal waste. Specific aspects of the irrigation control are discussed below, and it is to be appreciated that these aspects may be incorporated alone or in combination within the irrigation control of the present invention.

In a preferred embodiment, a user specific worksheet is created and contains the variables that the present invention utilizes to determine specific ETo value for users. In this worksheet, two potential weather data sources are typically listed. The two weather data options are free through an XML data feed. The first weather data source is the National Weather Service forecast available through http://forecast.weather.gov, and the second weather data source is the California Irrigation Management Information Systems (CIMIS) available through http://wwwcimis.water.ca.gov. For California users, CIMIS weather data would be ideal, because ETo is already calculated. For client elsewhere in the United States, the first weather data option should be used.

The weather data available through these sources may be automatically downloaded by means of XML and FTP data exchanges. Thus, to determine a specific evapotranspiration (ETo) value for any user location, the user should be prompted to enter their zip code during setup and registration of the controller on a computer via software or hardware interfaces. The zip code allows the server to determine the forecast weather data needed for a particular user.

Variables contained in the user specific worksheet are typical of those used to determine irrigation requirements. For instance, a suitable listing of these variables is available from a manual published by the Food and Agriculture Organization of the United Nations (FAO). Examples of geographically determined weather data may include Total ETo (in); Total Precip (in); Avg Sol Rad (Ly/Day); Avg. Vap Pres (mBars); Avg. Max Air Tmp (F); Avg. Min Air Tmp (F); Avg. Air Tmp (F); Avg. Max Rel Hum (%); Avg. Min Rel Hum (%); Avg. Rel Hum (%); Avg. Dew Point (F); Avg. Wind Speed (mph); and Avg. Soil Temp (F).

On the exemplary worksheet, each variable is utilized in the calculation of site-specific evapotranspiration ratings, utilizing the Penman-Montheith's ETo equation. The larger number of variables utilized in the calculations, the more accurate the result will be.

Solar radiation is a key factor in calculation of the evapotranspiration value. For the sum of solar radiation, Rn, the specific Ra values for a sunny day vary by degree of latitude. Ra is needed to determine the specific solar climate where a user is located. When the user inputs their zip code, the weather forecast databases provide latitudinal and longitudinal coordinates that can be used to identify Ra from values listed. Typically, when weather data indicates that it is a cloudy day in that region, the Ra value is only 75% of actual value.

In creating a user's profile, the yearly Ra values in addition to three-years of accumulated maximum, minimum, and average temperatures that apply may be uploaded to the central server. The temperature values and Ra may be used to calculate the monthly ETo in the event that the controller disconnects with central server. The offline ETo calculation is a simplified version of Penman-Montheith's equation, but less accurate.

Irrigating duration and scheduling may be automated within the central server and based on weather conditions available to the central server. The server continuously monitors real-time weather updates of daily and weekly weather forecasts. In order to maximize the benefits of irrigation, the irrigation time should be activated at the lowest temperature of the day. For example, if tomorrow's forecast predicts low temperature to be 65 degrees, the server takes note of the low temperature forecast and instructs the irrigation controller to initiate irrigation when the system detects that the user's current local temperature is 65 degrees. The server will send the daily ETo value to calculate ETi and signal the controller to irrigate once it finishes calculating the amount of time each irrigation zone needs based on the user's specific setup criteria.

The control station records the amount of local precipitation and ETo data sent from the central servers and calculates ETi. If it rains, a certain amount of precipitation is added to a zone for that irrigation period. If the accumulated precipitation exceeds the daily ETi, then the zone does not need additional irrigation until the sum of ETi exceeds accumulated precipitation determined from the available weather forecast data. The irrigation cycle returns to a normal pattern only after the ETi exceeds the accumulated precipitation level.

In a preferred embodiment, and as mentioned above in conjunction with step 910, a user can opt between a basic zone data mode and an advanced zone data mode. The basic mode has six options, namely a combination of sunny/mixed/shade, and turf/shrub. A user only has to assign a zone to a valve and simply pick the option that best fits that zone's landscape. The software or hardware interface would already have the average nozzle rate, microclimate, crop types, and crop density values defined as indicated on the worksheet.

For the advanced mode, four options are available for users to select and customize for individual zone. Microclimate, crop types, crop density, and nozzle specifications can be individually selected to fit the specifications of the landscape and irrigation system of the zone.

If necessary or desired, the user has the option to decrease and increase irrigation time from a range of −5% to 25% in increments of 5% to calibrate the amount of water irrigated. When the user adjusts the percent increments it decreases and increases the effective ETi values, which change the irrigation time since ETi divide by nozzle rate equal time.

To limit runoff and allow time for the soil to absorb irrigated water the determined irrigation time should be divided into two cycles and the break time between each cycle is the total irrigated time needed. If a zone is sloped then the irrigation time will be further divided into more cycles and the break in between irrigation is also based on the determined total irrigation time. A subcategory of different slope angles can be available for users to select, such as 3 cycles for 10 degree slope, 4 cycles for 20 degree slope, and 5 cycles for 30 degree slope, for example.

A user selects the specific vegetation types and the scale of density. The species factor (ks) accounts for variation in water needs by different plant species, divided into 3 categories (high, average, and low water need). To determine the appropriate category for a plant species, use plant manuals and professional experience. This factor is somewhat subjective; however, landscape professionals know the general water needs of plant species. Landscapes can be maintained in acceptable condition at about 50% of the reference evapotranspiration (ETa) value, and therefore the average value of ks is 0.5. If a species does not require irrigation once it is established, then the effective ks=0 0 and the resulting K_{L}=O.

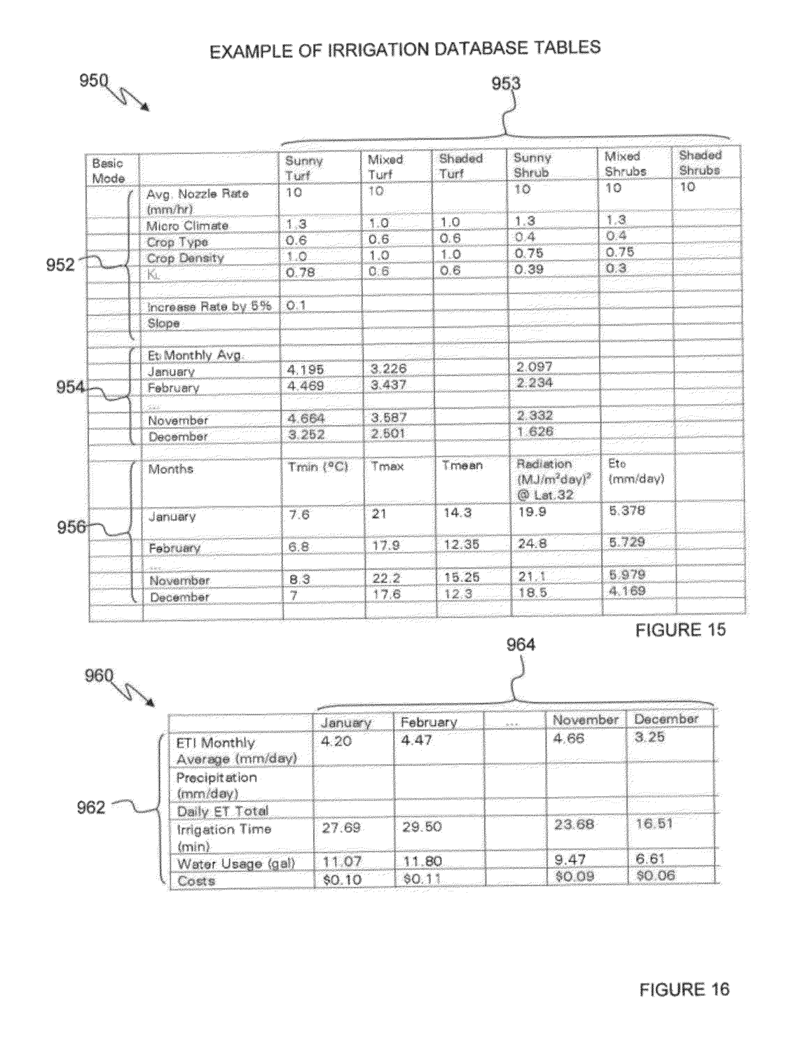

Referring to FIG. 15, an exemplary irrigation database table is shown and generally designated 950. Table 950 includes a listing of basic irrigation mode information 952 such as average nozzle rates, micro climate, crop types, crop density, and K_{L}, and a permutation of sunny/mixed/shaded and turf/shrub in columns 953. Section 954 of table 950 includes historical calculations of Eti by month based on the various vegetation and microclimate conditions. Section 956 includes the Tₘᵢₙ, Tₘₐₓ Tₘₑₐₙ, radiation data, and Eₜ₀ listed monthly. Utilizing the data in Table 950, the specific irrigation needs for a particular plant zone can be calculated.

FIG. 16 is another irrigation table generally designated 960, and summarizes actual data calculated, collected and verified by the central server of the present invention and providing irrigation consumption and cost histories. For example, section 962 of table 960 lists specific E_{Ti} daily average, recorded precipitation, daily Eₜ totals, irrigation time, water usage, and cost for the particular zone, and the data is summarized across section 964 by month. The data presented in table 960 provides a user with real-time feedback as to the true consumption of the irrigation system of the present invention.

Referring now to FIG. 17, a diagrammatical representation of the resource management and control system of the present invention is shown and generally designated 1000. The implementation of system 1000 includes an enlarged view of a typical user interface 1002 presented on the display 104 (shown in FIG. 1). User interface 1002, in a preferred embodiment, includes various popular application programs, such as Facebook™ 1004, FedEx™ 1006, and Maps 1008.

As shown in this Figure, it can be appreciated that the user interface 1002 on control station 108 represents a central hub of operation, or core computational device, for the home or light industrial facility into which the resource management and control system of the present invention is being incorporated. Specifically, as shown, the user interface includes many common icons representing the functionality of various applications, along with the icons specifically utilized by the present invention. It is contemplated that the resource management and control system of the present invention will supplement or supplant many other electronic communication products which are utilized in the home, and provide a central computing device capable of providing all aspects of the present invention, along with many of the other features presented and discussed herein.

In a preferred embodiment, a set of node-specific operational icons 1010-1024 are shown along the bottom edge of user interface 1002. For instance, the following node-specific icons are shown: water node icon 1010; energy node icon 1012; thermostat node icon 1014; calendar icon 1016; solar node icon 1018; gas node icon 1020, weather icon 1022, and irrigation node icon 1024.

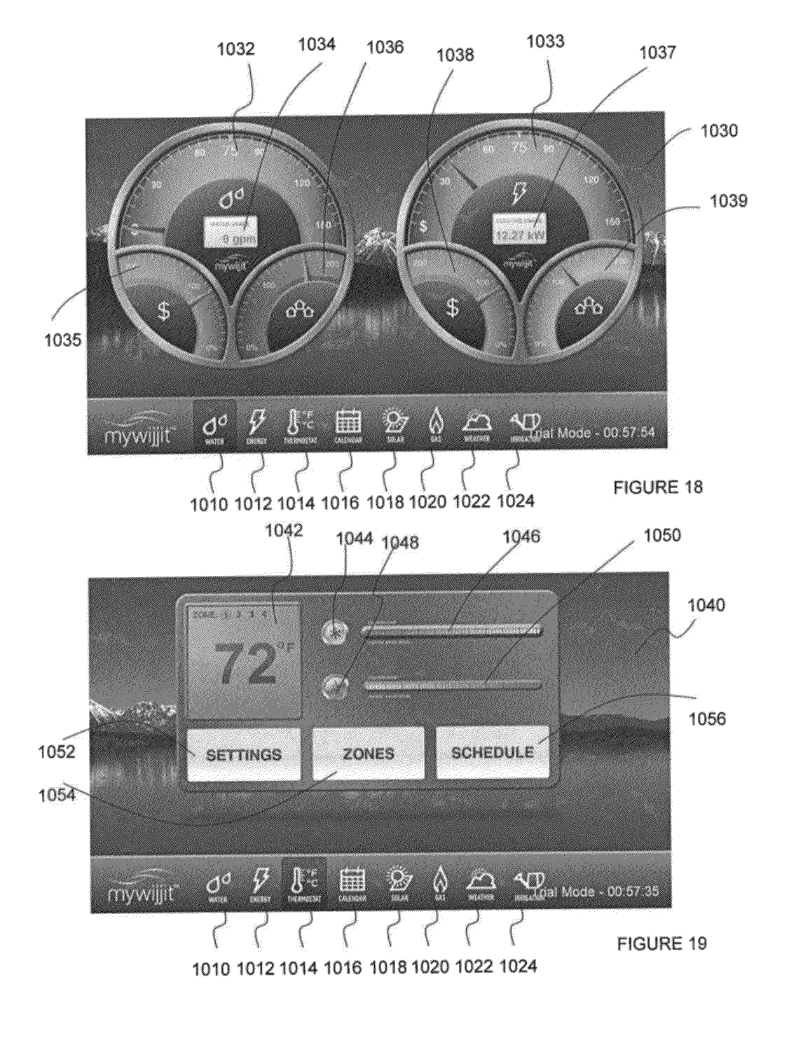

FIG. 18 is an example of the typical user interface of FIG. 17 with the water icon 1010 accessed. In this view, the standard user interface 1030, or “dashboard”, of the present invention is shown and includes a cumulative water usage gauge 1032, and a cumulative energy usage gauge 1033. Water usage gauge 1032 also displays the current consumption rate 1034 in numerical form, along with an accumulated cost in dial 1035, and a relative comparison to other users in a peer group, such as the neighborhood or region in dial 1036. Cumulative energy usage gauge 1033 also displays the current consumption rate 1037 in numerical form, along with an accumulated cost in dial 1038, and a relative comparison to other users in the neighborhood or region in dial 1039.

The basic user interface, or “dashboard,” provides users with an instantaneous assessment of their current, as well as cumulative energy consumption. Utilizing this real-time data, users can immediately adjust their consumption patterns and behavior to minimize their water and energy usage.

Referring now to FIG. 19, an example of the typical user interface of FIG. 17 with the thermostat icon 1014 accessed is shown and designated 1040. Thermostat display 1040 includes a numerical readout of the current interior zone temperatures 1042, and mode control buttons 1044 for cooling and 1048 for heating, along with corresponding consumption bars 1046 and 1050 to provide a graphical representation of the consumption associated with the heating or cooling mode. Page buttons are provided for monitoring settings 1052, zones 1054, and for scheduling 1056. Utilizing this interface, the user can monitor and control the environment within the house 102 precisely, and with the real-time feedback of consumption rates, energy consumption and expense can be minimized.

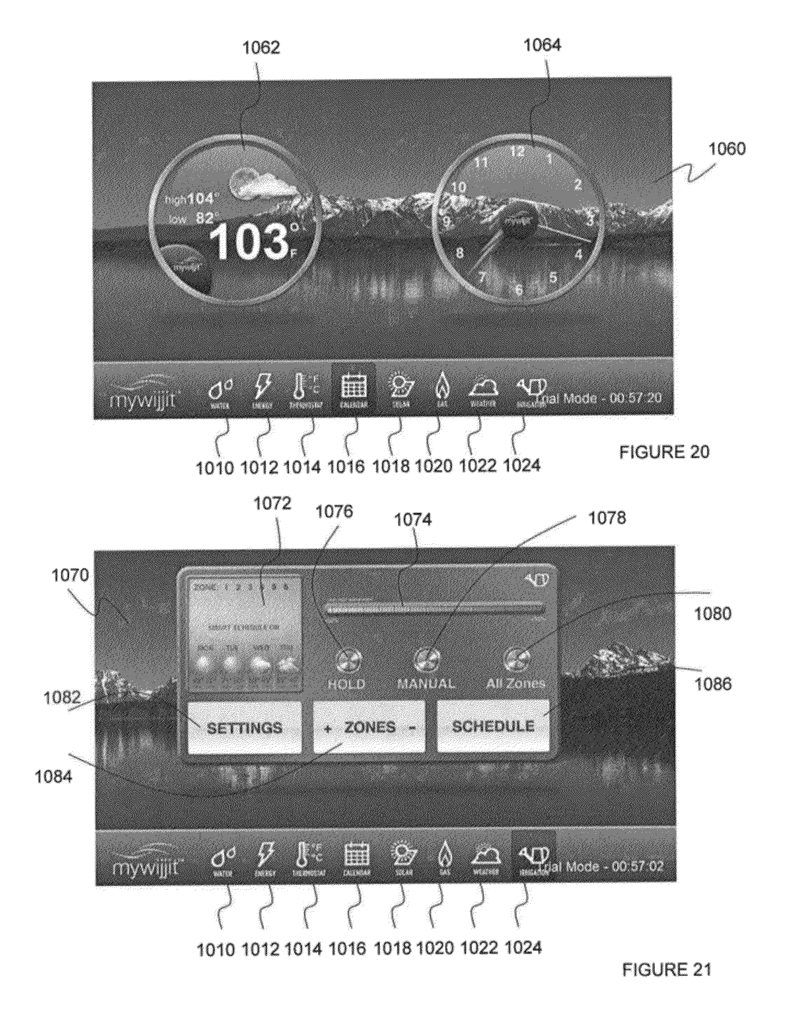

FIG. 20 is an example of the typical user interface of FIG. 17 with the calendar icon 1016 accessed. Using this calendar page 1060, the current temperature 1062, with projected high and low values, and time clock 1064 are shown. Users may access a calendar through this interface for scheduling events throughout the days, months and years.

FIG. 21 is an example of the typical user interface of FIG. 17 with the irrigation icon 1024 accessed, Irrigation display 1070 includes the current irrigation schedule 1072, and provides a graphical display 1074 of instantaneous consumption rates. In the event a user wants to adjust a particular irrigation schedule, hold button 1076, manual button 1078 or all zone selection 1080 may be selected. By selecting these user interface buttons, the irrigation schedule for any or all zones may be paused, overridden, or cancelled. Page buttons are provided for monitoring irrigation settings 1082, irrigation zones 1084, and for scheduling 1086. Accessing these buttons will allow a user to customize the operation of the irrigation system.

The system architecture of the resource management and control system of the present invention provides many user benefits. For instance, the Multi-Touch Screen Dashboard incorporated into the display server provides users with a simple to understand interface that is intuitive, easily viewable, and prominently located within the home. By providing the user with the ability to view usage history, and real-time usage metrics for the entire house, the user can take immediate steps to minimize consumption. This ability to instantaneously assess the current and historical consumption and costs of electricity, gas and water, provide a user with the ability to make decisions and behavioral changes resulting in optimal resource usage within their preferred budget. The user can automatically manage their own utility usage, and even compare their use to the average neighborhood usage.

By incorporating an autonomous Irrigation Control Process, excessive irrigation is avoided. In addition to consumption metrics, the resource management and control system of the present invention also provides for the management of energy production, such as through solar collectors or wind generators. The system can track solar production in real time, providing a user with instantaneous data regarding energy production.

Users can gain access and control of the resource management and control system of the present invention through WebControl, as well as virtually any other remote portable electronic device. This provides users with unlimited access and control of their utilities, even when absent from the home.

As the utility grid becomes increasingly overburdened, the resource management and control system of the present invention allows a user to receive messages and alerts from the power company requesting additional conservation efforts. Since the user can access the system from virtually anywhere, immediate conservation efforts can be realized. This demand response management and real-time load shedding capability can often prevent catastrophic failures in electrical supply, or the commonly occurring brown-out conditions that exist during peak consumption periods.

The customizable nature of the present invention provides the user, as well as the administrator, the ability to customize personal usage of utilities in order to optimize the value of the utilities, thereby minimizing costs. By utilizing the advantages of time-value billing, and focusing heavy use periods during those periods of lowest demand, significant savings can be realized. This time-value billing provides a user with the ability to conserve money while maintaining the comfort levels and utility uses within the home or light commercial property. Moreover, the ability to schedule when to operate the larger energy consuming projects in order to take advantage of the lower billing rates, allows a user to not only conserve the energy that they use, but also to minimize the money that they pay for that energy.

A feature of the resource management and control system of the present invention includes the centralized processing functions for the home or light industrial property. By utilizing the present invention, virtually all functions within the home or light industrial property may be monitored and controlled in accordance with prescribed savings programs, and can be real-time monitored in order to maximize the cost savings and minimize the energy usage of the property.

The resource management and control system of the present invention has been described to include several communication methods. For instance, communication links within the system have included wired, wireless, and PLC communication technologies that are known in the art. It is to be appreciated that node-to-node communication, as well as node to central server communication, may be achieved using any communication method known in the art.

The resource management and control system of the present invention has been described as suitable for new construction, as well as retrofit applications. Utilizing the wireless ZigBee communication products and protocol provides an effective wireless communication solution to all system components within the range of the ZigBee communication hardware. Power line communication (PLC) technologies also have an appropriate application in the resource management and control system of the present invention as it is particularly well suited for use in existing structures having radio frequency interference or multi-path issues. A PLC communication system as incorporated into the present invention utilizes the existing structural power wiring as a reliable digital communication medium without any deleterious effect on the power signals. These solutions, alone or in combination, provide a robust, easily to install retrofit application for existing homes and light industrial structures.

The unique open architecture, expandable platform, and wireless communication of the resource management and control system of the present invention provides a simple, turnkey energy management solution for both new and existing homes. The resource management and control system of the present invention, unlike any other system, allows a user to set and track savings goals, and to most importantly, save money.

1. A resource management and control system, comprising:
a central server having a memory in electrical communication with a computer system, a database within said memory and configured to contain operational instructions for said central server;
a control station comprising a home display server, a communication server, and a zigbee/plc server;
a plurality of nodes, each said node in communication with said control station through said zigbee/plc server wherein each said node is operably responsive to a control signal from said control station; and
a communication network in communication with said central server and said control station wherein said control station is operably responsive to a command from said central server.

2. The resource management and control system of claim 1, wherein the control station further comprises:
a central processing unit;
a memory in electrical communication with said central processing unit;
a database within said memory and configured to contain operational instructions for said central processing unit;
a user interface in communication with said central processing unit and said memory, said user interface including a display and a user input device; and
a communication server in communication with said communication network to exchange data and instruction signals between said central processing unit and said central server.

3. The resource management and control system of claim 1, further comprising a remote device in communication with said control station through said central server, said control station operatively responsive to a command signal from said remote device.

4. The resource management and control system of claim 1, further comprising external information resources in communication with said central server and selected from the set of: global real-time environmental data; national weather forecasts; historical weather data; utility company energy rate tables; user account data with past charges for water, electric and gas consumption; user real-time geographical location from location services, and peer group analytics.

5. The resource management and control system of claim 1, wherein said nodes further comprises a gas node, said gas node operably connected to said control station and configured to receive command instructions, to receive gas flow sensor data, and to report data to said control station.

6. The resource management and control system of claim 1, further comprising an environmental node, said environmental node operably connected to said control station and configured to receive command instructions, monitor environmental conditions, and to report said environmental conditions to said control station,

7. The resource management and control system of claim 1, further comprising an irrigation node operably connected to said control station and configured to receive command instructions, to receive water flow sensor data, and to report said water flow sensor data to said control station.

8. The resource management and control system of claim 1, further comprising a water node in electrical connection with and operably connected to said control station and configured to receive command instructions, to receive water flow sensor data, and to report said water flow sensor data to said control station.

9. The resource management and control system of claim 1, further comprising a solar node in electrical connection with an inverter configured to receive electrical power from a solar panel and to convert said electrical power to line voltage for use by a circuit breaker panel, and said solar node operably connected to said control station and configured to receive command instructions, to receive solar energy data, and to report said solar energy data to said control station.

10. The resource management and control system of claim 1, further comprising an electric node, said electrical node operably connected to said control station and configured to receive command instructions, to receive electrical energy data, and to report said electrical energy data to said control station.

11. The resource management and control system of claim 10, wherein said electric node further comprises a current sensing coil disposed about an electrical utility input and configured to sense electrical current passing through said electrical utility input.

12. The resource management and control system of claim 11, wherein said current sensing coil is a rogowski coil sensor.

13. The resource management and control system of claim 1, further comprising a vehicle node, said vehicle node operably connected to said control station and configured to receive command instructions, to receive vehicle energy data, and to report said vehicle energy data to said control station.

14. The resource management and control system of claim 1, further comprising a communication network operably connected to said control station and configured to transmit command instructions between said control station and said central server.

15. A resource management and control system, comprising:
a central server;
a control station comprising a home display server, a communication server, and a local communication server;
a plurality of nodes, each said node in communication with said control station through said local communication server wherein each said node is operably responsive to a control signal from said control station; and
a communication network in communication with said central server and said control station wherein said control station is operably responsive to a command from said central server.

16. The resource management and control system of claim 15, further comprising:
a means to monitor electricity consumption;
a means to monitor gas consumption; and
a means to monitor water use.

17. The resource management and control system of claim 15, further comprising:
a means to monitor high utility consumption devices; and
a means to control said high utility consumption devices.

18. The resource management and control system of claim 15, further comprising:
a means for providing time-of-use control; and
a means for adjusting one or more said node thereby maximizing energy and cost savings when considering the increased energy costs typically charged during peak periods of use.

19. The resource management and control system of claim 15, further comprising: a means to monitor solar production.

20. The resource management and control system of claim 15, further comprising wireless access nodes for interfacing various systems within a property to said control station.

21. The resource management and control system of claim 15, further comprising a means for monitoring said nodes.

22. The resource management and control system of claim 15, further comprising a means for diagnosing the function of said nodes.

23. The resource management and control system of claim 15, further comprising a means for alerting a user of failure of said node.

24. The resource management and control system of claim 15, further comprising a means for integrating a billing system to provide historical data for the cost of resource usage and production relative to time, geography and consumer service level agreements.

25. The resource management and control system of claim 15, further comprising:
a means for location services to sense the proximity of a consumer to the control station; and
said means for location services configured to control said resource management system to operably control one or more said nodes.

26. The resource management and control system of claim 15, further comprising a means to incorporate autonomously operating control processes, said autonomously operating control processes automatically configure and control devices for optimal resource consumption and application.
